(19) United States
(12) Patent Application Publication
(10) Pub. No.: US 2010/0283025 A1
(43) Pub. Date: Nov. 11, 2010

(54) Phase change devices

(76) Inventor: Semyon D. Savransky, Newark, CA (US)

Correspondence Address: Daniel R. Shepard;Contour Semiconductor, Inc., Bldg 5, 101 Billerica Ave., No. Billerica, MA, 01862, US

(21) Appl. No.: 12/800,007

(22) Filed: May 6, 2010

Related U.S. Application Data
(60) Provisional application No. 61/215,452, filed on May 6, 2009.

(51) Int. Cl. H01L 45/00; H01L 21/04; H01L 21/06

(52) U.S. Cl. 257/2; 438/478; 438/102; 257/E45.002; 257/E21.068; 257/E21.04

(57) ABSTRACT

A phase change device includes a native oxide grown on the surface of a first phase change alloy layer. The native oxide is punched through during the first electrical pulse applied between the device electrodes. An aperture created in the native oxide limit a region of localized heating during the device programming. A method for the phase change device fabrication includes a native oxide formation.

### CROSS REFERENCE TO RELATED APPLICATIONS

This application claims priority to and the benefit of, and incorporates herein by reference in its entirety, U.S. Provisional Patent Application No. 61/215,452 which was filed on May 6, 2010.

### REFERENCE TO A SEQUENCE LISTING, A TABLE, OR A COMPUTER PROGRAM LISTING COMPACT DISK APPENDIX

Not Applicable.

### REFERENCE REGARDING FEDERAL SPONSORSHIP

Not Applicable.

### STATEMENT REGARDING FEDERALLY SPONSORED RESEARCH OR DEVELOPMENT

Not Applicable.

### BACKGROUND OF THE INVENTION

1. Field of the Invention

The invention relates to phase-change devices and, in particular, to their architecture and processes for manufacturing.

2. Description of Related Art

The electric resistance of a phase change device varies in wide range under programming pulses. Resistance of phase-change devices can be read and programmed very quickly and do not require power to maintain their value. Therefore, phase change devices are very useful for non-volatile memories.

Other electrical properties of a phase change device (such as threshold switching voltage or capacitance) can be also altered by programming current pulses and values of these properties do not significantly change after programming. Therefore, phase change devices are very useful for reconfigurable electronics.

The high programming current is the main problem of phase change devices. It is possible to decrease the programming current by
a) Reduction of an active device volume;
b) Diminish heat losses during a device programming;
c) Selection of a robust phase change alloy with small thermal conductivity and low melting temperature.

Several patents and publications address the problem of high programming current. The only closest prior art documents are described here.

Breakdown device with insulator layer between two phase-change alloy layers is proposed in US Patent Application 20070200202 “Phase change memory structure having an electrically formed constriction” by Nowak and Lu. This device has small programming current but has pure yield (because phase change alloy sometimes not fill the electrically formed aperture) and relatively small endurance and programming current stability (because strong thermal mismatch of insulator and phase change alloy).

Double phase change alloy layer device is proposed in US Patent Application 20080186762 “Phase-change memory element”. This device has small programming current that is very sensitive to ill-controlled slope of pore between two phase change alloy layers and, as the result, different devices have different programming currents, hence it is difficult to create an apparatus that consist of several such devices.

The phase change devices should have small cost and good performance for all applications of these devices.

What is needed in the art is a phase change device with low-energy programming, high endurance, stability and retention and a simple method for such devices manufacturing.

### SUMMARY OF THE INVENTION

Broadly speaking, the embodiments of the present invention fill industry needs by providing robust and low-energy consuming phase change devices methods for their manufacturing.

New constructions of phase change devices are described in some embodiments of the present invention. A phase change device has native oxide that serves as breakdown layer between two phase change alloy(s) layers in one or more embodiments of the present invention. Methods of the phase change device with native oxide manufacturing are described in some embodiments of the present invention.

### BRIEF DESCRIPTION OF THE DRAWINGS

The invention is illustrated by way of example and not by way of limitation in the figures of the accompanying drawings in which like references indicate similar elements. It should be noted that references to “an” embodiment in this disclosure are not necessarily to the same embodiment, and they mean at least one.

FIG. 1A shows a generic phase change device with native oxide before the first pulse application.

FIG. 1B shows a generic phase change device with native oxide after the first pulse application.

FIG. 1C shows a generic phase change device with native oxide after a programming pulse application.

FIG. 2 illustrates a process of a phase change device fabrication flow chart.

### DETAILED DESCRIPTION

Several exemplary embodiments of the invention will now be described in details with reference to the accompanying drawings.

For the sake of simplicity only simplest phase change device and process of its fabrication are described in details below, although one or more embodiments of the invention are applicable for other types of phase change device and manufacturing processes.

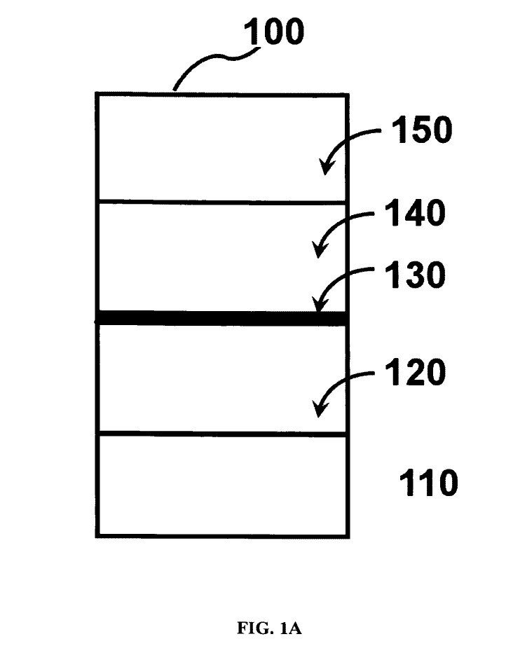

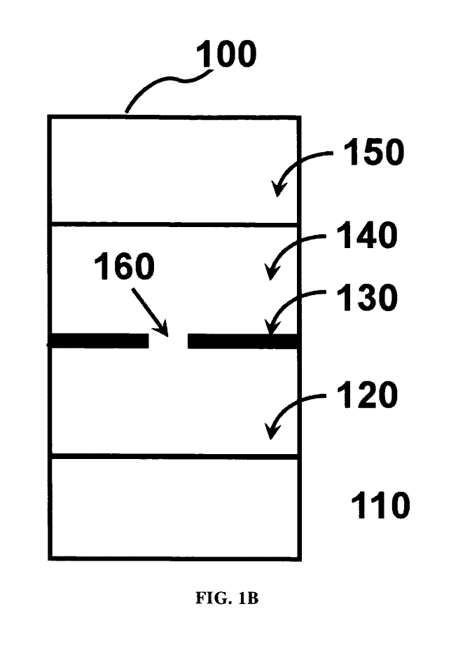

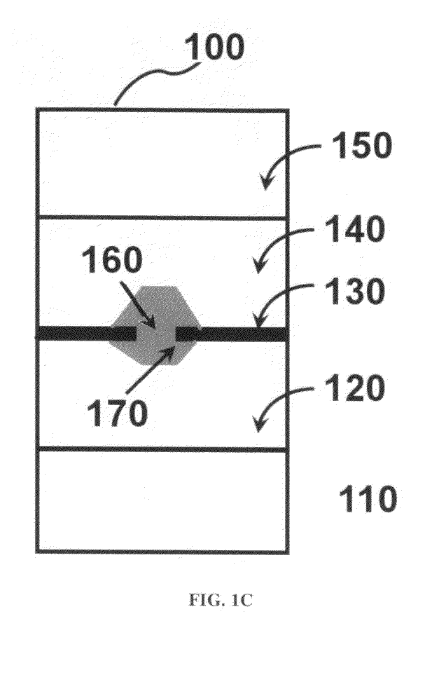

A phase change device 100 (FIG. 1A) has a first electrode 110, a first phase change alloy layer 120 formed on at least a portion of an upper surface of the first electrode 110, a native oxide 130 of the first phase change alloy 120 formed on an upper surface of the first phase change alloy 120, a second phase change alloy layer 140 formed on an upper surface of the native oxide 130, and a second electrode 150 formed on at least a portion of an upper surface of the at least second phase change alloy layer 140.

The electrodes 110 and 120 can be made from metals, doped or degenerate semiconductors, superconductors. Electrodes 110 and 120 can be made from the same material or from the different materials, e.g., from TiSiN or carbon.

The layers 120 and 140 can be made from the same or from different phase change alloys based on a chalcogene such as Te or Se or pnictide such as Sb or As, e.g. from Ge—Sb—Te and from In—Sb—Te.

At least one of the first 110 and second 150 electrodes has electrical conductivity equal or large than an electrical conductivity of at least one of the first 120 and second 140 phase change alloys. At least one of the first 110 and second 150 electrodes has thermal conductivity equal to or larger than a thermal conductivity of at least one of the first 120 and second 140 phase change alloys.

The phase change alloy 120 (or 140) has low viscosity above it glass transition temperature and can easily fill the aperture forming during the first electrical pulse that breaks the native oxide 130. In some embodiment the viscosity of the alloy 120 (or 140) is below 5 Poise at the melting temperature.

The native oxide 130 selected from the group consisting germanium oxide, silicon oxide, tellurium oxide, antimony oxide, indium oxide, gallium oxide has thickness below 20 nm, preferably below 3 nm.

The native oxide 130 has the thermal expansion coefficient close (or the same as) to the thermal expansion coefficient of phase change alloy 120 (or 140). The native oxide 130 has a small thermal conductivity close (or the same as) to the thermal expansion coefficient of phase change alloy 120 (or 140). The native oxide 130 has a small thermal boundary resistivity with phase change alloy 120 (or 140).

The breakdown voltage for native oxide 130 is smaller than 20V, preferably smaller than 1V. The breakdown current for native oxide 130 is smaller than 1 mA, preferably smaller than 10 uA. The duration of pulse that break the native oxide 130 is shorter than 1 ms, preferably shorter than 10 ns.

The native oxide 130 blocks electrical current flow between the electrodes 110 and 150 until a breakdown pulse is applied to the electrodes. The breakdown pulse opens an aperture 160 in the native oxide 130 as shown in FIG. 1B. The aperture 160 size is smaller than 50 nm, preferably smaller than 5 nm.

Electrical programming of the device 100 by a programming circuit coupled with the phase change device 100 brings a part 170 of at least one of the first and second phase change alloys 120 or/and 140 to a new state. The part 170 shown in FIG. 1C is located mostly within the aperture 160 in the native oxide 130. As the result of the programming a parameter of the device 100 is changed due to alteration of the part 170 of the alloy 120 or/and 140. The parameter is selected from the group consisting electrical resistance, impedance, capacitance, threshold switching voltage, optical reflectivity. A new value of the parameter can be read by at least one of interface devices coupled with the phase change device 100.

Phase change devices compromise at least K electrodes (K>2), at least L phase change alloy layers (L>2), at least M native oxides of phase change alloys formed on the layers' surfaces (1<M≦L), and at least two of phase change alloy layers are electrically connected with at least two electrodes in some embodiments of this invention.

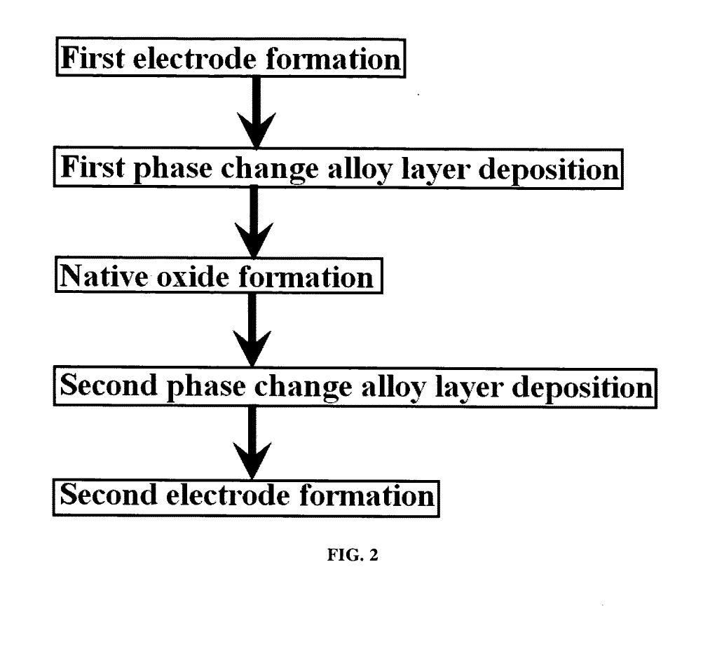

A flowchart for the device 100 manufacturing is shown in FIG. 2. The manufacturing includes standard steps of a semiconductor device process such as a first electrode 110 formation, a deposition of a first phase change alloy layer 120 on at least a portion of an upper surface of the first electrode 110, a formation a native oxide 130 at an upper surface of the first alloy 120, a deposition of a second phase change alloy layer 140 on at least a portion of the native oxide 130, and a formation of second electrode 150 on at least a portion of an upper surface of the at least second phase change alloy layer 140.

In order to create the native oxide 130 the chamber for a phase change alloy deposition is filled with oxygen or oxygen-contained gases that contact the upper surface of the first alloy 120 at temperatures between 20 deg. C. and 900 deg. C. in some embodiments.

Electron or ion beam creates a weak spot in native oxide 130 before the second layer 140 deposition during the device fabrication in some embodiments.

The formation method for at least one of the first 110 and second 150 electrodes selected from the group consisting thermal evaporation, spin-on a liquid, vacuum sputtering, chemical vapor deposition, atomic layer deposition, electrolyze. The deposition method for at least one of the first 120 and second 140 phase change alloys selected from the group consisting thermal evaporation, spin-on a liquid, vacuum sputtering, chemical vapor deposition, atomic layer deposition, electrolyze, sol-gel deposition. The deposition material for the first and second phase change alloys can be the same or different, and selected from the group consisting a chalcogenide (e.g. tellurium), a pnictide (e.g. antimony), germanium, silicon, indium, gallium.

At least one of the first and second phase change layers 120 or/and 140 is compromising more than one alloy in some embodiments. The group consisting germanium oxide, silicon oxide, tellurium oxide, antimony oxide, indium oxide, gallium oxide can be formed on the surface of the layer 120 during the native oxide 130 growth in some embodiments.

The electrodes 110 and 150 are formed from the group consisting metals, doped semiconductors, superconductors in some embodiments. The materials for electrodes 120 and 140 can be the same or different in some embodiments. Because the programming part 170 does not contact electrodes 120 and 140, the requirements to these electrodes are not so tight as the requirements for electrodes of phase change devices known in prior art.

The main advantage of some embodiments of this invention is the phase change devices with low programming current that can be manufactured in simple process with high yield. Proposed in some embodiments of this invention devices have high stability of the programming current during device functioning, high endurance and good performance. One skilled in the art can easily produce the phase change devices according to their architecture and manufacturing methods described in embodiments of this invention.

The foregoing description of an example of the preferred embodiment of the invention and the variations thereon have been presented for the purposes of illustration and description. It is not intended to be exhaustive or to limit the invention to the precise forms disclosed. Many modifications and variations are possible in light of the above teaching. It is intended that the scope of the invention be limited not by this detailed description.

I claim:

1. A phase change device comprising:
a first electrode;
a first phase change alloy layer formed on at least a portion of an upper surface of the first electrode;
a native oxide of the first phase change alloy formed on an upper surface of the first phase change alloy;
at least a second phase change alloy layer formed on an upper surface of the native oxide;
and a second electrode formed on at least a portion of an upper surface of the at least second phase change alloy layer.

2. The device of claim 1, wherein the first phase change alloy and the second phase change alloy have the same chemical composition.

3. The device of claim 1, wherein the first phase change alloy and the second phase change alloy have different chemical compositions.

4. The device of claim 1, wherein at least one of the first and second phase change alloys comprises a chalcogenide material.

5. The device of claim 1, wherein at least one of the first and second phase change alloys comprises a pnictide material.

6. The device of claim 1, wherein at least one of the first and second phase change alloys selected from the group consisting tellurium, or antimony, or germanium, or silicon, or indium, or gallium.

7. The device of claim 1, wherein the native oxide selected from the group consisting germanium oxide, silicon oxide, tellurium oxide, antimony oxide, indium oxide, gallium oxide.

8. The device of claim 1, wherein at least one of the first and second electrodes selected from the group consisting metals, doped semiconductors, superconductors, degenerate semiconductors.

9. The device of claim 1, wherein at least one of the first and second electrodes has electrical conductivity equal or large than an electrical conductivity of at least one of the first and second phase change alloys.

10. The device of claim 1, wherein at least one of the first and second electrodes has thermal conductivity equal or large than a thermal conductivity of at least one of the first and second phase change alloys.

11. The device of claim 1, wherein the native oxide thickness is smaller than 20 nm.

12. The device of claim 1, wherein the native oxide thickness is smaller than about 3 nm.

13. The device of claim 1, wherein the native oxide breakdown voltage is smaller than 20V.

14. The device of claim 1, wherein the native oxide breakdown voltage is smaller than about 1V.

15. The device of claim 1, wherein the native oxide breakdown current is smaller than 1 mA.

16. The device of claim 1, wherein the native oxide breakdown current is smaller than about 10 uA.

17. The device of claim 1, wherein the native oxide breakdown pulse is shorter than 1 ms.

18. The device of claim 1, wherein the native oxide breakdown pulse is shorter than about 10 ns.

19. The device of claim 1, wherein the breakdown pulse opens an aperture in the native oxide.

20. The device of claim 1, wherein the aperture size is less than 50 nm.

21. The device of claim 1, wherein the aperture size is less than about 5 nm.

22. The device of claim 1, wherein at least one of the first and second phase change alloys has low viscosity above their glass transition temperature.

23. The device of claim 1, wherein at least one of the first and second phase change alloys has viscosity below 5 Poise at the melting temperature.

24. The device of claim 1, wherein at least one of the first and second phase change alloys fills the aperture in the native oxide after the breakdown pulse.

25. The device of claim 1, wherein a programming of at least one of the first and second phase change alloys to a desired value of a parameter occurs mostly within aperture in the native oxide.

26. The device of claim 1, wherein the parameter selected from the group consisting electrical resistance, impedance, capacitance, threshold switching voltage, optical reflectivity.

27. A method of a phase change device fabrication comprising:
a first electrode formation;
a deposition of a first phase change alloy layer on at least a portion of an upper surface of the first electrode;
a formation a native oxide at an upper surface of the first alloy;
a deposition of a second phase change alloy layer on at least a portion of the native oxide;
a formation of second electrode on at least a portion of an upper surface of the at least second phase change alloy layer.

28. The method of claim 27, wherein oxygen contacts the upper surface of the first alloy during the native oxide growth.

29. The method of claim 27, wherein temperature during the native oxide growth is lower than 900 deg

30. The method of claim 27, wherein temperature during the native oxide growth is higher than 20 deg

31. The method of claim 27, wherein the formation method for at least one of the first and second electrodes selected from the group consisting thermal evaporation, spin-on a liquid, vacuum sputtering, chemical vapor deposition, atomic layer deposition, electrolyze.

32. The method of claim 27, wherein the deposition method for at least one of the first and second phase change alloys selected from the group consisting thermal evaporation, spin-on a liquid, vacuum sputtering, chemical vapor deposition, atomic layer deposition, electrolyze, sol-gel deposition.

33. The method of claim 27, wherein the deposition material for the first and second phase change alloys is the same.

34. The method of claim 27, wherein the deposition materials for the first and second phase change alloys are different.

35. The method of claim 27, wherein the deposition material for at least one of the first and second phase change alloys contains a chalcogenide.

36. The method of claim 27, wherein the deposition material for at least one of the first and second phase change alloys contains a pnictide.

37. The method of claim 27, wherein at least one of the first and second phase change layers is compromising more than one alloy

38. The method of claim 27, wherein at least one of the first and second phase change alloys selected from the group consisting tellurium, or antimony, or germanium, or silicon, or indium, or gallium.

39. The method of claim 27, wherein the native oxide selected from the group consisting germanium oxide, silicon oxide, tellurium oxide, antimony oxide, indium oxide, gallium oxide.

40. The method of claim 27, wherein at least one of the first and second electrodes selected from the group consisting metals, doped semiconductors, superconductors.

41. The method of claim 27, wherein the material of the first and second electrodes is the same.

42. The method of claim 27, wherein the materials of the first and second electrodes are different.

43. The method of claim 27, wherein an electron beam is used to create a weak spot in the native oxide before the second phase change alloy layer deposition.

44. The method of claim 27, wherein an ion beam is used to create a weak spot in the native oxide before the second phase change alloy layer deposition.

45. A phase change device comprising:
at least K electrodes, where K>2;
at least L phase change alloy layers, where L>2;
at least M native oxides of phase change alloys formed on the layers' surfaces, where 1<M≦L;
and at least two of phase change alloy layers are electrically connected with at least two electrodes.
